(19) United States
(12) Patent Application Publication
(10) Pub. No.: US 2026/0114107 A1
(43) Pub. Date: Apr. 23, 2026

(54) LIGHT-EMITTING DEVICE AND LIGHTING APPARATUS USING THE SAME

(71) Applicants: CITIZEN ELECTRONICS CO., LTD., Yamanashi-ken (JP); CITIZEN WATCH CO., LTD., Tokyo (JP)

(72) Inventor: Yasuaki KAYANUMA, Yamanashi-ken (JP)

(21) Appl. No.: 19/147,885

(22) PCT Filed: Jan. 18, 2024
(86) PCT No.: PCT/JP2024/001219

§ 371 Date: Jul. 14, 2025

(30) Foreign Application Priority Data
Jan. 26, 2023 (JP) 2023-010227

(51) Int. Cl. H10H 29/80; F21K 9/68; F21K 9/69; F21V 5/04; F21V 7/06; F21Y 105/16; F21Y 105/18; F21Y 115/10; H10H 29/24; H10H 29/85; H10H 29/855; H10H 29/856

(52) U.S. Cl. CPC H10H 29/922; F21K 9/68; F21K 9/69; H10H 29/855; H10H 29/856; H10H 29/857; H10H 29/942; F21V 5/045; F21V 7/06; F21Y 2105/16; F21Y 2105/18; F21Y 2115/10; H10H 29/24

(57) ABSTRACT

A light-emitting device includes a substrate, power supply terminals on the substrate, first light-emitting elements and second light-emitting elements configured to emit light by supplying electric power between the power supply terminals, and a light exit surface configured to allow exit of light emitted from these light-emitting elements. The light exit surface includes a first light exit region being a plane region, and second light exit regions being a plane region not including the first light exit region. A light-emitting element group has a first light-emitting element group configured with a plurality of first light-emitting elements in the first light exit region, and a second light-emitting element group configured with a plurality of second light-emitting elements in the second light exit region. An average luminance of light exited from the first light exit region is higher than that from the second light exit region.

### TECHNICAL FIELD

The present invention relates to a light-emitting device in which a large number of light-emitting elements are arranged, and a lighting apparatus using the light-emitting device.

### BACKGROUND ART

A light-emitting device has been known which is configured to emit light by mounting a large number of LED (Light-Emitting-Diode) elements in a light-emitting area having a small area. For example, Patent Literature 1 describes a light-emitting device in which a large number of LED elements are grouped by a predetermined number, and series connection and parallel connection are mixed together. The light-emitting device described in Patent Literature 1 is capable of preventing a driving voltage from becoming higher, and is also capable of reducing light emission variation of individual LED elements.

### CITATION LIST

### Patent Literature

PTL1: JP 2011-9298 A

### DISCLOSURE OF THE INVENTION

### Problems to be Solved by the Invention

However, in the light-emitting device described in PTL1, the number of parallels of the LED elements is identical for each group, and an electric current of an identical current value passes through the individual LED elements, so that the individual LED elements emit an equal amount of light. Therefore, with a lighting apparatus using the light-emitting device described in PTL1, it becomes difficult to enhance irradiation in a specific direction.

Accordingly, it is an object of the present invention to provide a light-emitting device capable of efficiently enhancing irradiation in a specific direction by disposing a region having a high average luminance and a region having a low average luminance on a light exit surface, and also provide a lighting apparatus using the light-emitting device.

### Means of Solving the Problem

A light-emitting device according to the present invention includes a substrate, a pair of power supply terminals disposed on the substrate, a plurality of first light-emitting elements and a plurality of second light-emitting elements which are configured to emit light by supplying electric power between the pair of power supply terminals, and a light exit surface configured to allow exit of light emitted from the plurality of first light-emitting elements and the plurality of second light-emitting elements. The light exit surface includes a first light exit region being a plane region including a centroid of the light exit surface in plan view, and a second light exit region being a plane region not including the first light exit region. The plurality of first light-emitting elements constitute a first light-emitting element group by being disposed in the first light exit region in plan view. The plurality of second light-emitting elements constitute a second light-emitting element group by being disposed in the second light exit region in plan view. An average luminance of light exited from the first light exit region is higher than an average luminance exited from the second light exit region.

In a light-emitting device according to the present invention, the first light-emitting element group includes at least one first light-emitting element row where a plurality of first light-emitting elements are arranged, a clearance between individual elements of the plurality of first light-emitting elements constituting the first light-emitting element row is smaller than an element size of the first light-emitting element, and the plurality of first light-emitting elements are connected in series. The second light-emitting element group includes a plurality of second light-emitting element rows where the plurality of second light-emitting elements are arranged. A clearance between individual elements of the plurality of second light-emitting elements constituting the second light-emitting element rows is smaller than an element size of the second light-emitting element. The plurality of second light-emitting elements are connected in series.

A lighting apparatus according to the present invention includes the light-emitting device and a condenser disposed above the light exit surface.

### Effects of the Invention

With the light-emitting device according to the present invention, it is possible to efficiently enhance irradiation from the light-emitting device toward a specific direction because the average luminance of light exited from the first light exit region including the centroid of the light exit surface is set higher than the average luminance of light exited from the second light exit region not including the first light exit region.

Also, with the light-emitting device according to the present invention, it is possible to reduce occurrence of color unevenness of light emitted from the light-emitting device because the clearance between the individual elements of the plurality of first light-emitting elements constituting the first light-emitting element row is set smaller than the element size of the first light-emitting element, and the clearance between the individual elements of the plurality of second light-emitting elements constituting the second light-emitting element rows is set smaller than the element size of the second light-emitting element.

With the lighting apparatus according to the present invention, it is possible to provide lighting in which irradiation in a specific direction with less occurrence of color unevenness can be enhanced efficiently because of using the light-emitting device according to the present invention.

Further, with the lighting apparatus according to the present invention, it is possible to provide environmentally friendly lighting with less light pollution because the light-emitting device according to the present invention is used to enhance an emission in a specific direction and turn down an emission in directions other than the specific direction. Additionally, electric energy of electric power supplied can be reduced to contribute to SDGs.

### BRIEF DESCRIPTION OF THE DRAWINGS

FIG. 1A is a perspective view of a light-emitting device according to a first embodiment of the present invention.

FIG. 1B is a plan view of the light-emitting device according to the first embodiment of the present invention.

FIG. 2 is an enlarged plan view of a range surrounded by a broken line A in FIG. 1A.

FIG. 3 is a circuit diagram of the light-emitting device according to the first embodiment of the present invention.

FIG. 4A is a diagram showing a front chromaticity due to a difference in ratio of number of rows at a temperature color of 2700 K.

FIG. 4B is a diagram showing a front chromaticity due to a difference in ratio of number of rows at a temperature color of 5000 K.

FIG. 5 is a diagram schematically showing color unevenness of light emitted from a condenser of the light-emitting device.

FIG. 6 is a diagram showing examples of element size ratios that are different depending on element arrangement.

FIG. 7 is a graph showing area ratio of color unevenness of the light-emitting device with respect to element size ratio.

FIG. 8 is a plan view of a light-emitting device according to a second embodiment of the present invention.

FIG. 9 is a plan view of a light-emitting device according to a third embodiment of the present invention.

FIG. 10 is a plan view of a light-emitting device according to a fourth embodiment of the present invention.

FIG. 11 is a plan view of a light-emitting device according to a fifth embodiment of the present invention.

FIG. 12 is a circuit diagram of the light-emitting device according to the fifth embodiment of the present invention.

FIG. 13 is a circuit diagram of the light-emitting device according to the sixth embodiment of the present invention.

FIG. 14A is a characteristic diagram (part 1) showing luminous intensity distributions of a lighting apparatus using the light-emitting device according to the first embodiment of the present invention, and a lighting apparatus using a light-emitting device according to a comparative example.

FIG. 14B is a characteristic diagram (part 2) showing luminous intensity distributions of the lighting apparatus using the light-emitting device according to the first embodiment of the present invention, and the lighting apparatus using the light-emitting device according to the comparative example.

FIG. 14C is a characteristic diagram (part 3) showing luminous intensity distributions of the lighting apparatus using the light-emitting device according to the first embodiment of the present invention, and the lighting apparatus using the light-emitting device according to the comparative example.

FIG. 15A is a front view of the lighting apparatus using the light-emitting device according to the first embodiment of the present invention.

FIG. 15B is a plan view of the lighting apparatus using the light-emitting device according to the first embodiment of the present invention.

FIG. 16 is a cross-sectional view of a condenser lens disposed above the light-emitting device.

FIG. 17A is a plan view of a light-emitting device according to a comparative example.

FIG. 17B is a circuit diagram of the light-emitting device according to the comparative example.

FIG. 18 is a perspective view of a light-emitting device including a plurality of light exit surfaces.

### DESCRIPTION OF EMBODIMENTS

Referring to the drawings, a light-emitting device and a lighting apparatus according to the present invention are described below. However, it should be noted that a technical scope of the present invention is not limited to their embodiments but covers the inventions described in the claims and their equivalents.

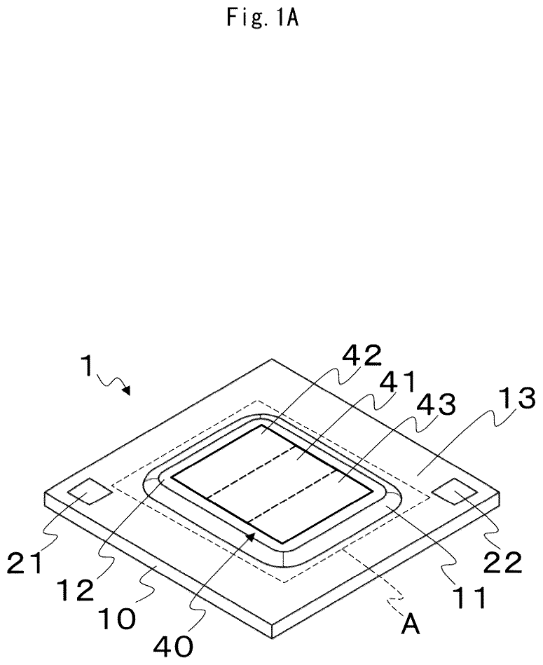

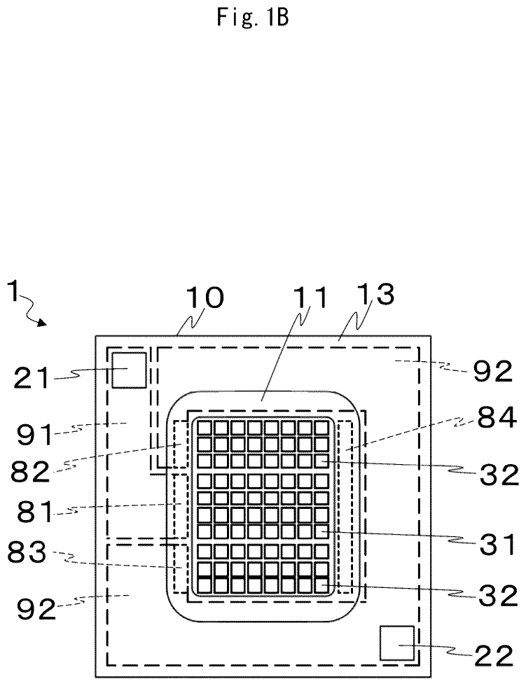

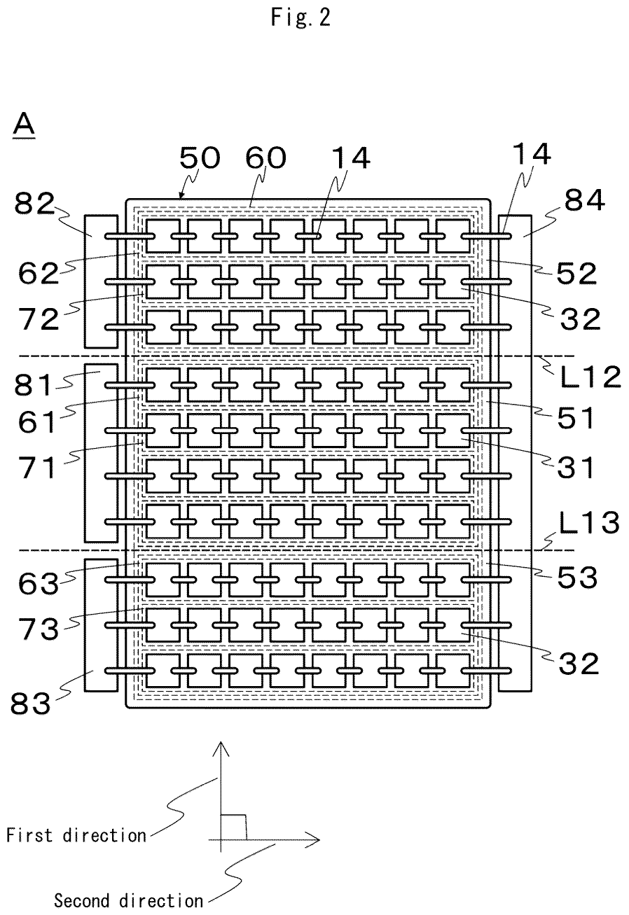

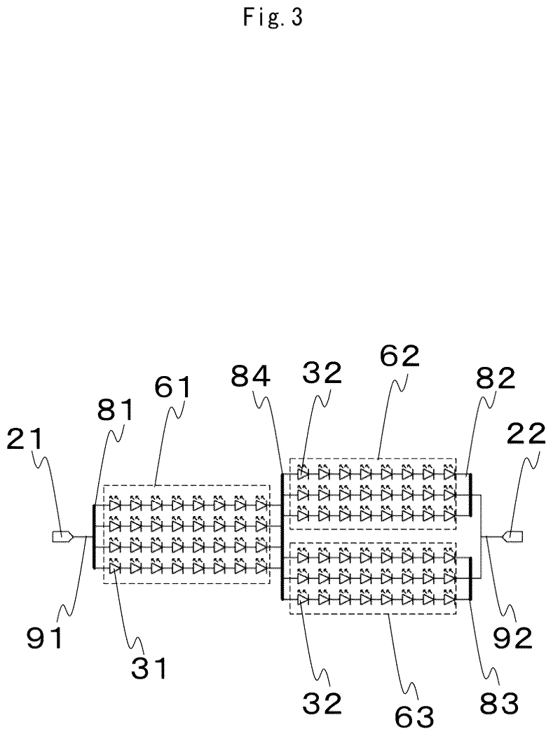

FIG. 1A is a perspective view of a light-emitting device 1 according to a first embodiment of the present invention, and FIG. 1B is a plan view of the light-emitting device 1. In FIG. 1B, a bonding wire 14 and a sealing material 12 shown in FIG. 1A are omitted. FIG. 2 is an enlarged plan view of a range surrounded by a broken line A shown in FIG. 1A. In FIG. 2, a reflection frame body 11 and the sealing material 12 shown in FIG. 1A, and first power supply wiring 91 and second power supply wiring 92 shown in FIG. 1B are omitted. FIG. 3 is a circuit diagram of a light-emitting device according to the first embodiment.

The light-emitting device 1 according to the first embodiment includes a substrate 10, a first power supply terminal 21 and a second power supply terminal 22 that are a pair of power supply terminals, a plurality of first light-emitting elements 31 and a plurality of second light-emitting elements 32 that constitute a light-emitting element group 60, the reflection frame body 11, and the sealing material 12. LEDs are used as the first light-emitting elements 31 and the second light-emitting elements 32.

The substrate 10 is a laminated substrate where a lower surface of a circuit board formed by an insulating material, such as glass epoxy resin, etc., is bonded to an upper surface of a mounting board made of metal having a high thermal conductivity, such as aluminum. An upper surface of the substrate 10 includes a mounting region 50 where the plurality of first light-emitting elements 31 and the plurality of second light-emitting elements 32 that constitute the light-emitting element group 60 are mounted with an insulating adhesive, etc. interposed therebetween. The circuit board may have a planar shape having approximately the same external shape as the mounting board, and may be provided with an opening surrounding the mounting region 50. A highly light reflective film may be disposed on the upper surface of the mounting board. The substrate 10 may be a substrate made from a ceramic having a high thermal conductivity. A planar shape of the substrate 10 may be a polygonal shape or an oval shape. In the present embodiment, the substrate 10 has a planar shape of a square with a side length of 20 mm.

The first power supply terminal 21 and the second power supply terminal 22 that are a pair of power supply terminals are disposed at both corners on a diagonal line on the upper surface of the substrate 10. The first power supply terminal 21 and the second power supply terminal 22 are wiring patterns formed by a conductive thin film of copper, etc. in order to supply electric power supplied from an external power source (not shown) to the plurality of first light-emitting elements 31 and the plurality of second light-emitting elements 32 mounted on the mounting region 50. The first power supply terminal 21 and the second power supply terminal 22 may be subjected to solder plating or gold plating. An electronic member, such as a connector, may be mounted on the first power supply terminal 21 and the second power supply terminal 22. The first power supply terminal 21 and the second power supply terminal 22 may be disposed on a lateral surface of the substrate 10, or may be disposed on a bottom surface of the substrate 10.

The light-emitting element group 60 is an element group configured with a first light-emitting element group 61 and a pair of second light-emitting element groups 62 and 63 disposed on both sides of the first light-emitting element group 61.

The first light-emitting element group 61 is a light-emitting element group configured with a plurality of first light-emitting element rows 71. The first light-emitting element row 71 is a light-emitting element row configured with a plurality of first light-emitting elements 31. The plurality of first light-emitting elements 31 constituting the first light-emitting element row 71 are connected in series by a bonding wire 14. The plurality of first light-emitting element rows 71 constituting the first light-emitting element group 61 are connected in parallel by the bonding wire 14 between a first power supply pad 81 and an opposing electrode pad 84 disposed on both sides of the first light-emitting element row 71 with the row 71 interposed therebetween. In the present embodiment, the first light-emitting element group 61 is configured with four first light-emitting element rows 71, and the first light-emitting element row 71 is configured with eight first light-emitting elements 31.

The second light-emitting element group 62 disposed on one side of the first light-emitting element group 61 is a light-emitting element group configured with a plurality of second light-emitting element rows 72. The second light-emitting element row 72 is a light-emitting element row configured with a plurality of second light-emitting elements 32. The plurality of second light-emitting elements 32 constituting the second light-emitting element row 72 are connected in series by the bonding wire 14. The plurality of second light-emitting element rows 72 constituting the second light-emitting element group 62 are connected in parallel by the bonding wire 14 between the opposing electrode pad 84 and the second power supply pad 82 that are disposed on both sides of the second light-emitting element row 72 with the row 72 interposed therebetween. In the present embodiment, the second light-emitting element group 62 is configured with three second light-emitting element rows 72, and the second light-emitting element row 72 is configured with eight second light-emitting elements 32.

The second light-emitting element group 63 disposed on the other side of the first light-emitting element group 61 is a light-emitting element group configured with a plurality of second light-emitting element rows 73. The second light-emitting element row 73 is a light-emitting element row configured with a plurality of second light-emitting elements 32. The plurality of second light-emitting elements 32 constituting the second light-emitting element row 73 are connected in series by the bonding wire 14. The plurality of second light-emitting element rows 73 constituting the second light-emitting element group 63 are connected in parallel by the bonding wire 14 between the opposing electrode pad 84 and a third power supply pad 83 that are disposed on both sides of the second light-emitting element row 73 with the row 73 interposed therebetween. In the present embodiment, the second light-emitting element group 63 is configured with three second light-emitting element rows 73, and the second light-emitting element row 73 is configured with eight second light-emitting elements 32. The light-emitting elements constituting the second light-emitting element row 73 disposed on the other side are configured with the same second light-emitting elements 32 as the light-emitting elements constituting the second light-emitting element row 72 disposed on the one side. The number of the second light-emitting elements 32 constituting the second light-emitting element row 73 is equal to the number of the second light-emitting elements 32 constituting the second light-emitting element row 72.

The number of rows of the first light-emitting element rows 71 constituting the first light-emitting element group 61 is smaller than the number of rows obtained by adding the number of rows of the second light-emitting element rows 72 and 73 respectively constituting the pair of second light-emitting element groups 62 and 63. In the present embodiment, the number of rows of the first light-emitting element rows 71 constituting the first light-emitting element group 61 is two rows fewer than the number of rows obtained by adding the number of rows of the second light-emitting element rows 72 and 73 respectively constituting the second light-emitting element groups 62 and 63.

The first light-emitting element 31 is a blue LED die having a rectangular planar shape which includes an anode electrode and a cathode electrode, and emits blue light according to application of a forward voltage between the anode electrode and the cathode electrode. A dominant wavelength of the blue light emitted from the first light-emitting element 31 falls within a range between 445 nm and 495 nm. The first light-emitting element 31 is formed by laminating a PN junction layer formed by a gallium nitride layer on a sapphire substrate that is a transparent substrate. In the present embodiment, the first light-emitting element 31 has a planar shape of a square with a side length of 0.7 mm, and a dominant wavelength of the blue light emitted from the first light-emitting element 31 is 450 nm.

The second light-emitting element 32 is a blue LED die having a rectangular planar shape which includes an anode electrode and a cathode electrode, and emits blue light according to application of a forward voltage between the anode electrode and the cathode electrode. A dominant wavelength of the blue light emitted from the second light-emitting element 32 falls within a range between 445 nm and 495 nm. The second light-emitting element 32 is formed by laminating a PN junction layer formed by a gallium nitride layer on a sapphire substrate that is a transparent substrate. The second light-emitting element 32 may be a light-emitting element having the same properties as the first light-emitting element 31. The second light-emitting element 32 may be a light-emitting element having a smaller element size than the first light-emitting element 31. In the present embodiment, the second light-emitting element 32 is a light-emitting element having the same properties as the first light-emitting element 31.

The mounting region 50 is a region where the plurality of first light-emitting elements 31 and the plurality of second light-emitting elements 32, each constituting the light-emitting element group 60, are mounted on the upper surface of the substrate 10. The mounting region 50 includes a first mounting region 51 and a pair of second mounting regions 52 and 53 disposed on both sides of the first mounting region 51. The first mounting region 51 and the second mounting regions 52 and 53 are disposed adjacent to each other in a stripe shape. The first mounting region 51 is disposed in a surface region including a centroid of a light exit surface 40, that is, between the pair of left and right second mounting regions 52 and 53 at a central part of the mounting region 50. The second mounting regions 52 and 53 are spaced apart from each other by interposing the first mounting region 51 therebetween. A planar shape of the mounting region 50 is preferably a rectangular shape. Boundary lines L12 and L13 indicating a boundary of the first mounting region 51 and the second mounting regions 52 and 53 are preferably a straight line parallel to a second direction shown in FIG. 2. In the present embodiment, the planar shape of the mounting region 50 is the rectangular shape, and the boundary line L12 and the boundary line L13 are the straight line parallel to the second direction.

The plurality of first light-emitting elements 31 constituting the first light-emitting element group 61 are mounted on the first mounting region 51. A light-emitting element constituting a light-emitting element group other than the first light-emitting element group 61 is not mounted on the first mounting region 51. A planar shape of the first mounting region 51 is preferably a minimum rectangular shape that can accommodate all of the plurality of first light-emitting elements 31 mounted on the first mounting region 51. The first light-emitting elements 31 mounted on the first mounting region 51 may be disposed at intervals of equal length in parallel to a first direction shown in FIG. 2, or may be disposed at intervals of equal length in parallel to the second direction. In the present embodiment, the first light-emitting elements 31 mounted on the first mounting region 51 are disposed at intervals of 1.0 mm in parallel to the first direction, and are disposed at intervals of 1.0 mm in parallel to the second direction. In that case, a clearance between the first light-emitting elements 31 adjacent to each other is 0.3 mm that is smaller than a size of each of vertical and horizontal sides of each of the first light-emitting elements 31. The size of each of vertical and horizontal sides of the element is also called an element size.

The plurality of second light-emitting elements 32 constituting the second light-emitting element groups 62 and 63 are mounted on the second mounting regions 52 and 53.

A light-emitting element constituting a light-emitting element group other than the second light-emitting element groups 62 and 63 is not mounted on the second mounting regions 52 and 53. A planar shape of the second mounting regions 52 and 53 is preferably a minimum rectangular shape that can accommodate all of the plurality of second light-emitting elements 32 mounted on the second mounting regions 52 and 53. The second light-emitting elements 32 mounted on the second mounting regions 52 and 53 may be disposed at intervals of equal length in parallel to the first direction, or may be disposed at intervals of equal length in parallel to the second direction. A length of the interval along which the second light-emitting elements 32 mounted on the second mounting regions 52 and 53 are disposed in the first direction is preferably equal to or larger than a length of the interval along which the first light-emitting elements 31 mounted on the first mounting region 51 are disposed in the first direction. A length of the interval along which the second light-emitting elements 32 mounted on the second mounting regions 52 and 53 are disposed in the second direction is preferably equal to or larger than a length of the interval along which the first light-emitting elements 31 mounted on the first mounting region 51 are disposed in the second direction. In the present embodiment, the second light-emitting elements 32 mounted on the second mounting regions 52 and 53 are disposed at intervals of 1.0 mm in parallel to the first direction, and are disposed at intervals of 1.0 mm in parallel to the second direction. In this case, a clearance between the second light-emitting elements 32 adjacent to each other is 0.3 mm that is smaller than the size of each of the vertical and horizontal sides of each of the second light-emitting elements 32.

The first direction described above is a direction in which the first mounting region 51 and the second mounting regions 52 and 53 are disposed adjacent to each other in the stripe shape. The second direction is a direction perpendicular to the first direction on the upper surface of the substrate 10.

In the present embodiment, similarly to the clearance between the individual elements, a clearance in the first direction between each of the first light-emitting elements 31 of the first light-emitting element row 71 mounted on both ends of the first mounting region 51 and each of the second light-emitting elements 32 of the second light-emitting element rows 72 and 73 mounted on one end adjacent to the first light-emitting element row 71 in the pair of second mounting regions 52 and 53 is smaller than a size of the vertical and horizontal sides of each of the first light-emitting element 31 and the second light-emitting element 32.

Thus in the present embodiment, the clearance between the individual elements of the first light-emitting element 31 and the second light-emitting element 32, the clearance between the individual rows of the plurality of first light-emitting element rows 71 and second light-emitting element rows 72 and 73, and the clearance between the first light-emitting element row 71 and the second light-emitting element rows 72 and 73 are smaller than the size of the vertical and horizontal sides of each element. Consequently, light exited from a light exit region of the light-emitting device can be well mixed between the elements to reduce color unevenness. Hence, with a lighting apparatus, etc. using the light-emitting device, it is possible to obtain excellent lighting effects with less color unevenness.

The first power supply pad 81, the opposing electrode pad 84, the second power supply pad 82, and the third power supply pad 83 are wiring patterns formed by a conductive thin film of copper, etc., which are disposed in the vicinity of the mounting region 50 on the upper surface of the substrate 10. The first power supply pad 81, the opposing electrode pad 84, the second power supply pad 82, and the third power supply pad 83 may be subjected to gold plating. The first power supply pad 81, the opposing electrode pad 84, the second power supply pad 82, and the third power supply pad 83 are preferably covered with the reflection frame body 11 that surrounds a rectangular light exit surface 40 described later in a rectangular frame shape. The reflection frame body 11 is a dam having a rectangular frame shape disposed around the first light-emitting element group 61 and the second light-emitting element groups 62 and 63, and the first power supply pad 81, the opposing electrode pad 84, the second power supply pad 82, and the third power supply pad 83 are disposed on a lower surface side of the dam.

The first power supply pad 81 is disposed in the vicinity of the first mounting region 51 on the upper surface of the substrate 10. The first power supply pad 81 is coupled via the first power supply wiring 91 to the first power supply terminal 21. The first power supply pad 81 is coupled via the bonding wire 14 to the anode electrode of the first light-emitting element 31 at an initial stage of each of the first light-emitting element rows 71 constituting the first light-emitting element group 61. The term “the light-emitting element at the initial stage of the light-emitting element row” described in the present specification means a light-emitting element in which the anode electrode is coupled via the power supply pad and the bonding wire at one end of the light-emitting element row configured with a plurality of light-emitting elements connected in series.

The opposing electrode pad 84 is disposed in the vicinity of the mounting region 50 opposed to the first power supply pad 81 with the first mounting region 51 interposed therebetween on the upper surface of the substrate 10. The opposing electrode pad 84 is coupled via the bonding wire 14 to the cathode electrode of the first light-emitting element 31 at a final stage of each of the first light-emitting element rows 71 constituting the first light-emitting element group 61. The opposing electrode pad 84 is also coupled via the bonding wire 14 to the anode electrode of the second light-emitting element 32 at the initial stage of each of the second light-emitting element rows 72 and 73 respectively constituting the second light-emitting element groups 62 and 63. The term “the light-emitting element at the final stage of the light-emitting element row” described in the present specification means a light-emitting element in which the cathode electrode is coupled via the power supply pad and the bonding wire at the other end of the light-emitting element row configured with a plurality of light-emitting elements connected in series.

The second power supply pad 82 and the third power supply pad 83 are disposed in the vicinity of the second mounting regions 52 and 53 opposed to the opposing electrode pad 84 with the second mounting regions 52 and 53 interposed therebetween on the upper surface of the substrate 10. The second power supply pad 82 and the third power supply pad 83 are coupled via the second power supply wiring 92 to the second power supply terminal 22. The second power supply pad 82 and the third power supply pad 83 are coupled via the bonding wire 14 to the cathode electrode of the second light-emitting element 32 at the final stage of each of the second light-emitting element rows 72 and 73 respectively constituting the second light-emitting element groups 62 and 63.

The first power supply pad 81, the second power supply pad 82, and the third power supply pad 83 are individually disposed in the vicinity of an identical side of the mounting region 50 opposed to the opposing electrode pad 84 with the mounting region 50 interposed therebetween on the upper surface of the substrate 10.

The bonding wire 14 is a wire formed by a conductor, such as gold and copper. A part electrically coupled by the bonding wire 14 may be coupled by a wiring pattern, which is formed by a conductive thin film of copper, etc., disposed on the upper surface of the substrate 10, instead of the bonding wire 14.

The first power supply wiring 91 and the second power supply wiring 92 are a wiring pattern formed by a conductive thin film of copper, etc. disposed on the upper surface of the substrate 10. The first power supply wiring 91 couples the first power supply terminal 21 and the first power supply pad 81. The second power supply wiring 92 couples the second power supply terminal 22, the second power supply pad 82, and the third power supply pad 83. The first power supply wiring 91 and the second power supply wiring 92 may be covered with an insulating film 13 that is also called a solder resist. The first power supply wiring 91 and the second power supply wiring 92 may be configured with a plurality of wiring patterns coupled via a conductive jumper member. An electronic member, such as a zener diode or capacitor, may be coupled between the first power supply wiring 91 and the second power supply wiring 92.

The reflection frame body 11 is made of a synthetic resin, such as a silicone resin containing white particles of titanium oxide, etc., and has an optical reflectance of 80% or more. The reflection frame body 11 is the dam that is disposed so as to surround the light-emitting element group 60 on the upper surface of the substrate 10 and prevents leakage of the sealing material 12.

The sealing material 12 is a synthetic resin material whose base material is a transparent resin, such as a silicone resin, and which contains a phosphor. The sealing material 12 is disposed so as to cover the mounting region 50 and the light-emitting element group 60 in a region surrounded by the reflection frame body 11. The phosphor contained in the sealing material 12 is, for example, YAG, CASN, SCASN, or KSF, or a mixture of these. The phosphor is a wavelength conversion member that absorbs blue light emitted from the first light-emitting element 31 and the second light-emitting element 32, and emits light after being subjected to wavelength conversion into red, green, yellow color, etc.

The light-emitting device 1 emits synthetic light of the blue light emitted from the first light-emitting element 31 and the second light-emitting element 32, and the light after being subjected to wavelength conversion which is emitted from the phosphor contained in the sealing material 12, from the light exit surface 40 that is the upper surface of the sealing material 12.

The light exit surface 40 formed in a rectangular shape includes a first light exit region 41 at a central part that is a plane region including a centroid of the light exit surface, and a pair of second light exit regions 42 and 43 that are plane regions disposed on both sides of the first light exit region 41 and do not include the first light exit region 41. The first light exit region 41 and the second light exit regions 42 and 43 indicate regions overlapped in the same shape at the same positions as the first mounting region 51 and the second mounting regions 52 and 53 in plan view.

As shown in FIGS. 1A and 1B, and FIG. 3, when a potential difference of a threshold value or more is applied between the first power supply terminal 21 and the second power supply terminal 22 in the light-emitting device 1, an electric current flows from the first power supply terminal 21 toward the second power supply terminal 22 to supply electric power. When the electric current flows from the first power supply terminal 21 toward the second power supply terminal 22, the plurality of first light-emitting elements 31 and the plurality of second light-emitting elements 32, each constituting the light-emitting element group 60 mounted on the mounting region 50, light up as shown in FIG. 2.

The number of rows of the first light-emitting element row 71 constituting the first light-emitting element group 61 is smaller than the number of rows obtained by adding the numbers of rows of the second light-emitting element rows 72 and 73 respectively constituting the second light-emitting element groups 62 and 63. Therefore, an electric current value of an electric current flowing through each of the plurality of first light-emitting elements 31 constituting the first light-emitting element group 61 becomes larger than an electric current value of an electric current flowing through each of the plurality of second light-emitting elements 32 constituting the second light-emitting element groups 62 and 63.

Accordingly, an amount of luminous flux of light emitted from each of the plurality of first light-emitting elements 31 constituting the first light-emitting element group 61 mounted on the first mounting region 51 becomes larger than an amount of luminous flux of light emitted from each of the plurality of second light-emitting elements 32 constituting the second light-emitting element groups 62 and 63.

The plurality of first light-emitting elements 31 constituting the first light-emitting element group 61, and the plurality of second light-emitting elements 32 constituting the second light-emitting element groups 62 and 63 are respectively disposed at equal intervals in the first mounting region 51 and the second mounting regions 52 and 53. Therefore, an average luminance of light exited from the first light exit region 41 is higher than an average luminance of light exited from the second light exit regions 42 and 43.

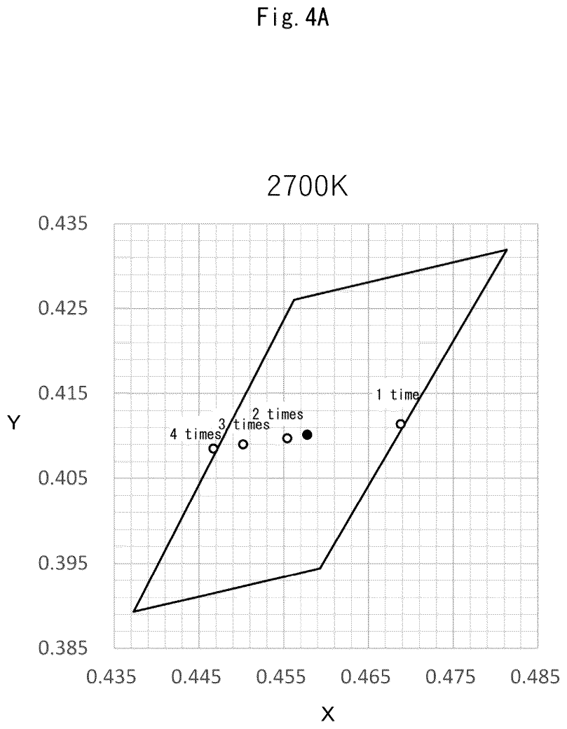

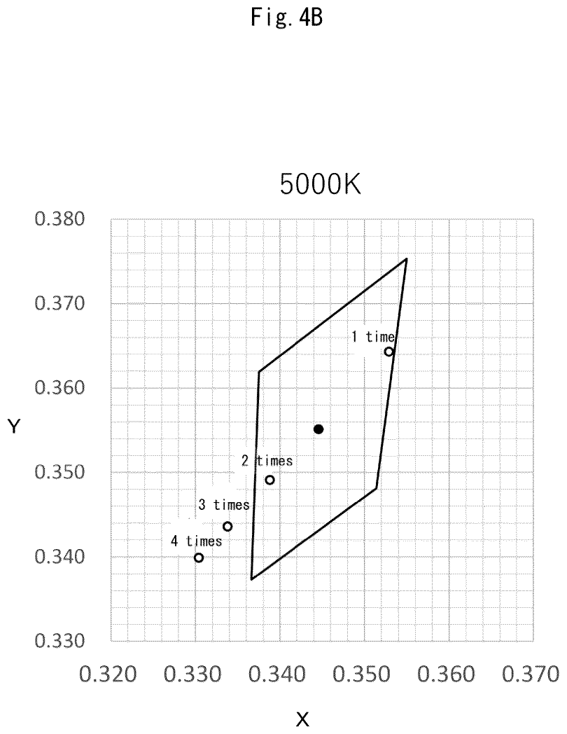

FIGS. 4A and 4B are diagrams showing a shift of front chromaticity when a ratio of number of rows is set to 1, 2, 3, and 4. The term “ratio of number of rows” is a value obtained by dividing a sum of the numbers of rows of the second light-emitting element rows 72 and 73 respectively constituting the second light-emitting element groups 62 and 63 by a value of the number of rows of the first light-emitting element rows 71 constituting the first light-emitting element group 61. Black points shown in FIGS. 4A and 4B are XY chromaticity coordinates respectively indicating centers of color temperatures 2700K and 5000K standardized by ANSI NEMA ANSLG C78.377-2015. Ranges surrounded by a quadrangular shape shown in FIGS. 4A and 4B are XY chromaticity coordinates respectively indicating acceptable ranges of color temperatures 2700K and 5000K standardized by ANSI NEMA ANSLG C78.377-2015.

As shown in FIG. 4A, in a case where the phosphor contained in the sealing material 12 is set so as to fall within the acceptable range of color temperature 2700K by setting the ratio of number of rows to 1, it is outside the acceptable range if the ratio of number of rows is set to 4, and it is necessary to change setting conditions of the phosphor. In contrast, it falls within the acceptable range if the ratio of number of rows is 3 or less, and it is therefore unnecessary to change the setting conditions of the phosphor. Accordingly, the ratio of number of rows is preferably 3 or less.

As shown in FIG. 4B, if the phosphor contained in the sealing material 12 is set so as to fall within the acceptable range of color temperature 5000K by setting the ratio of number of rows to 1, it is outside the acceptable range if the ratio of number of rows is set to 3, and it is necessary to change setting conditions of the phosphor. In contrast, it falls within the acceptable range if the ratio of number of rows is 2 or less, and it is therefore unnecessary to change the setting conditions of the phosphor. Accordingly, the ratio of number of rows is more preferably 2 or less.

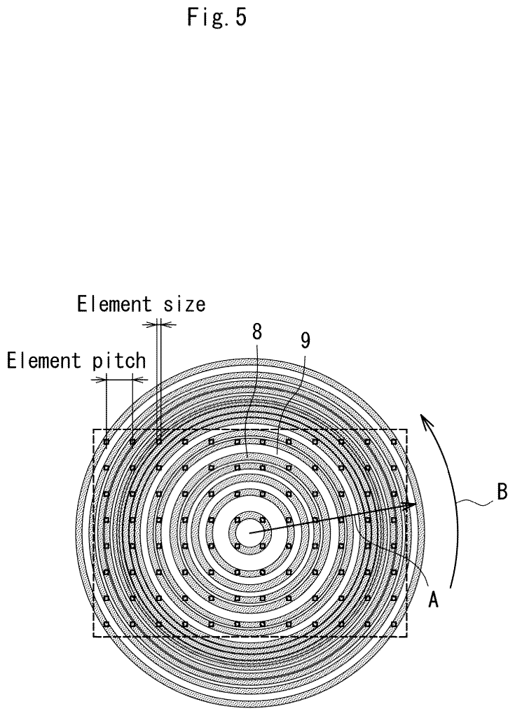

Next, a relationship between an interval of light-emitting elements with respect to an element size of the individual light-emitting elements constituting the light-emitting element group 60 of the light exit surface 40 and color unevenness in the light-emitting device 1 is described based on FIGS. 5 to 7. The interval of the light-emitting elements is also called an element pitch. FIG. 5 schematically shows color unevenness of light emitted from the condenser of the light-emitting device. A ring-shaped black band 8 indicates a part where lights emitted from the individual light-emitting elements appear as well mixed light, and a ring-shaped white band 9 indicates a part where lights emitted from the individual light-emitting elements are insufficiently mixed and appear as color unevenness. Because the light emitted from the condenser has a larger aberration in a sagittal direction B (rotational direction) than an aberration in a tangential direction A (radial direction), color unevenness occurs in multiple concentric circles as shown in FIG. 5.

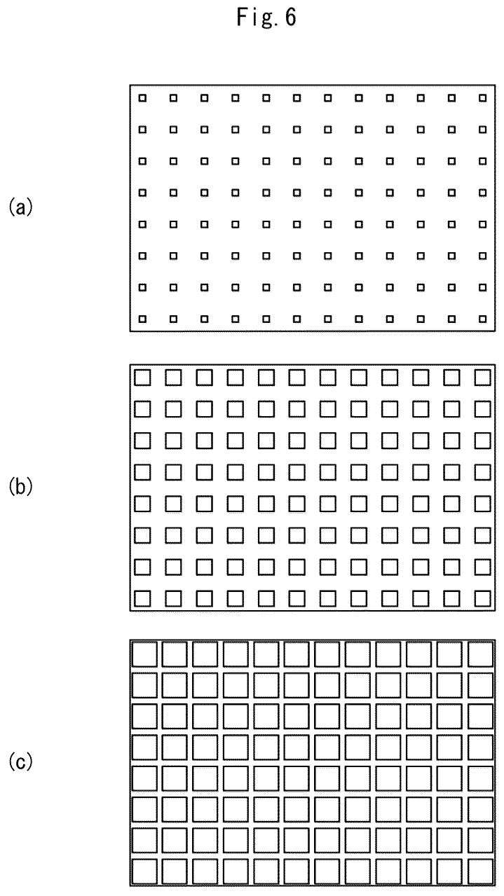

FIG. 6 shows examples of element size ratios that differ depending on element arrangement. Incidentally, these are represented by element size ratio=element size/element pitch. The example of element arrangement shown in FIG. 6A is the case of the element pitch of 5 with respect to the element size of 1, and an element size ratio is approximately 20%. In this case, a clearance between elements is four times the element size. The example of element arrangement shown in FIG. 6B is the case of the element pitch of 2 with respect to the element size of 1, and an element size ratio is approximately 50%. In this case, a clearance between elements is approximately equal to the element size. The example of element arrangement shown in FIG. 6C is the case of the element pitch of 1.25 with respect to the element size of 1, and an element size ratio is approximately 80%. In this case, a clearance between elements is significantly smaller than the element size.

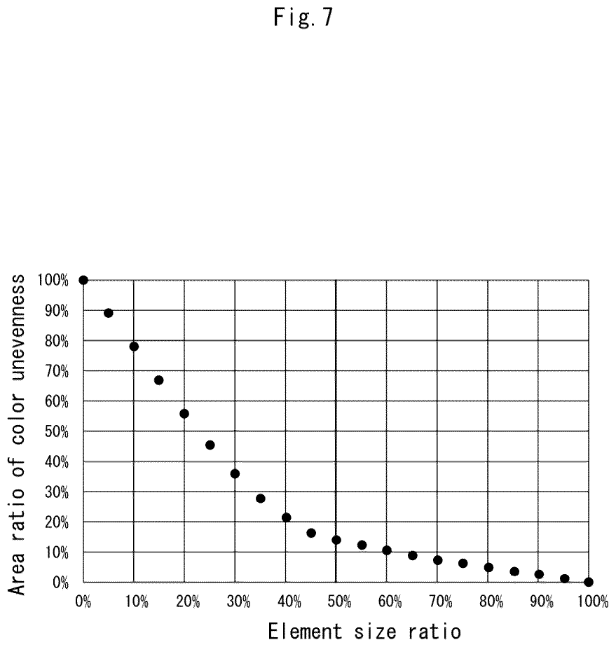

FIG. 7 is a graph showing area ratio of color unevenness of the light-emitting device with respect to element size ratio. The area ratio of color unevenness is calculated based on an area of the black band 8 and an area of the white band 9 in FIG. 5. Incidentally, it is represented by area ratio of color unevenness=area of white band/area of black band+area of white band. This graph shows that the area ratio of color unevenness changes significantly from an element size ratio of 50%, and color unevenness is less likely to occur at 50% or more. That is, it can be seen that the occurrence of color unevenness is effectively reducible by setting the clearance between elements adjacent to each other so as to be equal to or smaller than the element size.

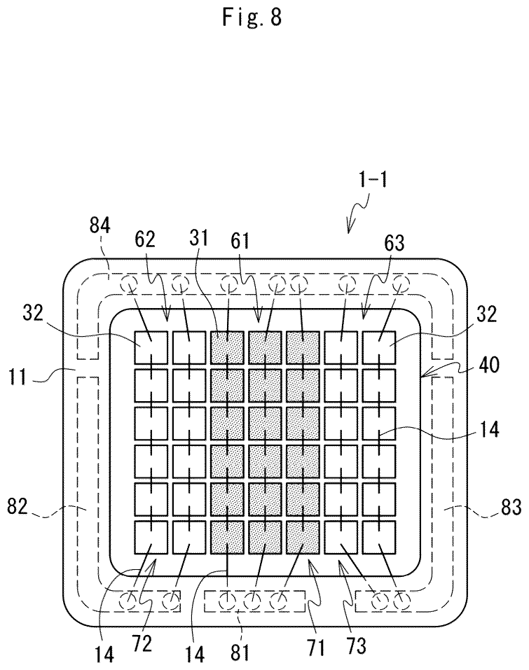

FIG. 8 shows a light-emitting device 1-1 according to a second embodiment of the present invention. The light-emitting device 1-1 is one in which a light exit surface 40 formed in a rectangular shape is surrounded by a reflection frame body 11 having a rectangular frame shape. Similarly to the previous embodiment, the light exit surface 40 is configured with a first light exit region at a central part that is a plane region including a centroid of the light exit surface, and a pair of second light exit regions that are disposed on both sides of the first light exit region. A first light-emitting element group 60 corresponds to the first light exit region, and second light-emitting element groups 62 and 63 correspond to the second light exit regions. The first and second light-emitting element groups constitute the light-emitting element groups mounted on a mounting region of the light exit surface.

In this embodiment, the first light-emitting element group 61 is a light-emitting element group configured with three first light-emitting element rows 71. The first light-emitting element row 71 is a light-emitting element row configured with six first light-emitting elements 31. The plurality of first light-emitting elements 31 constituting the first light-emitting element row 71 are connected in series by a bonding wire 14. The three first light-emitting element rows 71 constituting the first light-emitting element group 61 are connected in parallel by the bonding wire 14 between a first power supply pad 81 and an opposing electrode pad 84 respectively disposed on both sides of the first light-emitting element row 71 with the row 71 interposed therebetween.

The second light-emitting element groups 62 and 63 respectively disposed on both sides of the first light-emitting element group 61 are light-emitting element groups respectively configured with two second light-emitting element rows 72 and 73. Each of the second light-emitting element rows 72 and 73 is a light-emitting element row configured with six second light-emitting elements 32. The plurality of second light-emitting elements 32 constituting the second light-emitting element rows 72 and 73 are connected in series by the bonding wire 14. The plurality of second light-emitting element rows 72 and 73 respectively constituting the second light-emitting element groups 62 and 63 are connected in parallel by the bonding wire 14 between the opposing electrode pad 84, a second power supply pad 82, and a third power supply pad 83 disposed on both sides of the second light-emitting element rows 72 and 73 with the rows 72 and 73 interposed therebetween.

In this embodiment, a clearance between elements of the first light-emitting element 31 and the second light-emitting element 32 is smaller than a light-emitting element size. A clearance between rows of the first element row 71 and the second light-emitting element rows 72 and 73 is also smaller than the light-emitting element size.

In the light-emitting device 1-1 according to this embodiment, the first power supply pad 81, the second power supply pad 82, the third power supply pad 83, and the opposing electrode pad 84 are disposed on a lower surface side of a reflection frame body 11 having a rectangular frame shape surrounding the light exit surface 40. The first power supply pad 81 is coupled to a first power supply terminal (not shown), and the second power supply pad 82 and the third power supply pad 83 are coupled to a second power supply terminal (not shown). When an electric current flows from the first power supply terminal toward the second power supply terminal, the plurality of first light-emitting elements 31 and the plurality of second light-emitting elements 32, each constituting the light-emitting element group mounted on the mounting region light up.

Similarly to the first embodiment, the number of rows of the first light-emitting element row 71 constituting the first light-emitting element group 61 is smaller than the number of rows obtained by adding the numbers of rows of the second light-emitting element rows 72 and 73 respectively constituting the second light-emitting element groups 62 and 63. Therefore, an electric current value of an electric current flowing through each of the plurality of first light-emitting elements 31 constituting the first light-emitting element group 61 becomes larger than an electric current value of an electric current flowing through each of the plurality of second light-emitting elements 32 constituting the second light-emitting element groups 62 and 63. Accordingly, an amount of luminous flux of light emitted from each of the plurality of first light-emitting elements 31 constituting the first light-emitting element group 61 mounted on the first mounting region becomes larger than an amount of luminous flux of light emitted from each of the plurality of first light-emitting elements 32 constituting the second light-emitting element groups 62 and 63. The plurality of first light-emitting elements 31 constituting the first light-emitting element group 61, and the plurality of second light-emitting elements 32 constituting the second light-emitting element groups 62 and 63 are respectively disposed at equal intervals in the first mounting region and the second mounting regions. Therefore, an average luminance of light emitted from the first light exit region is higher than an average luminance of light emitted from the second light exit regions.

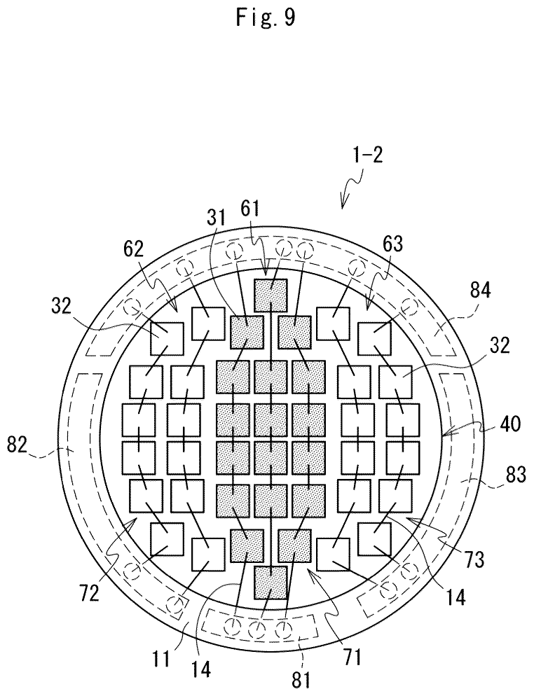

FIG. 9 shows a light-emitting device 1-2 according to a third embodiment of the present invention. The light-emitting device 1-2 has the same configuration as the light-emitting device 1-1 according to the second embodiment, but has a different shape of the light exit surface 40, a different shape of the reflection frame body 11, and a different arrangement shape of the light-emitting elements. Therefore, the same reference numerals are used for common structural members, and a detailed description thereof will be omitted. The light-emitting device 1-2 is one in which a light exit surface 40 formed in a circle is surrounded by a reflection frame body 11 having a ring shape. A first power supply pad 81, a second power supply pad 82, a third power supply pad 83, and an opposing electrode pad 84 are disposed on a lower surface side of the reflection frame body 11 having a rectangular frame shape surrounding the light exit surface 40.

In three first light-emitting element rows 71 constituting the first light-emitting element group 61 in this embodiment, three first light-emitting elements 31 at both ends in each row are disposed at positions near the reflection frame body 11, specifically, at individual apexes of a triangle. The second light-emitting element rows 72 and 73 respectively disposed in two rows on the left side and on the right side, which constitute the second light-emitting element groups 62 and 63, are arranged so as to draw a curve along the reflection frame body. Thus, an arrangement of the first light-emitting elements 31 and the second light-emitting elements 32 corresponds to the circular light exit surface 40, and it is therefore possible to obtain sufficient luminance and reduce color unevenness in a part close to the reflection frame body 11 in the light exit surface 40.

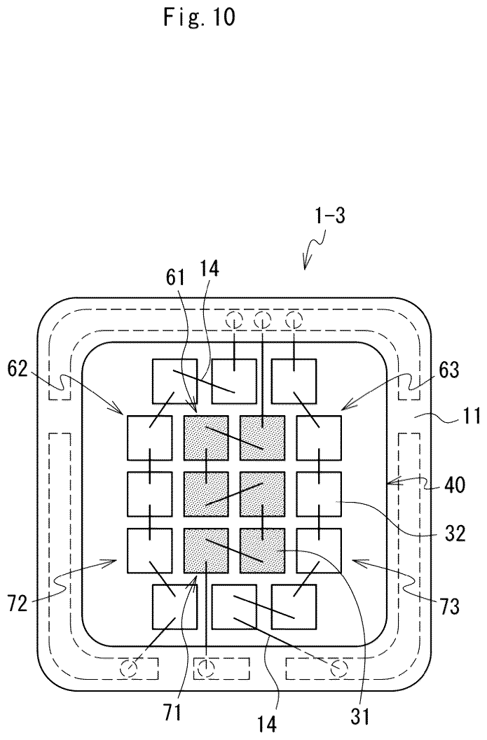

FIG. 10 shows a light-emitting device 1-3 according to a fourth embodiment of the present invention. The light-emitting device 1-3 has the same configuration as the light-emitting device 1-1 according to the second embodiment, but has a different arrangement shape of the light-emitting elements and a different number of the light-emitting element rows. Therefore, the same reference numerals are used for common structural members, and a detailed description thereof will be omitted.

In this embodiment, there is only one first light-emitting element row 71 constituting the first light-emitting element group 61. Six first light-emitting elements 31 constituting the first light-emitting element row 71 are disposed at a central part of the light exit surface 40. Second light-emitting element rows 72 and 73 respectively constituting second light-emitting element groups 62 and 63 are configured with a total of 12 second light-emitting elements 32, which are disposed so as to surround the first light-emitting element 31. Two rows of each of the second light-emitting element rows 72 and 73 are configured with six second light-emitting elements 32. Thus, the first light-emitting elements 31 are disposed at the central part of the light exit surface 40, and the second light-emitting elements 32 surround the first light-emitting elements 31. Consequently, luminance of the central part of the light exit surface 40 can be enhanced, and its surroundings have uniform lightness.

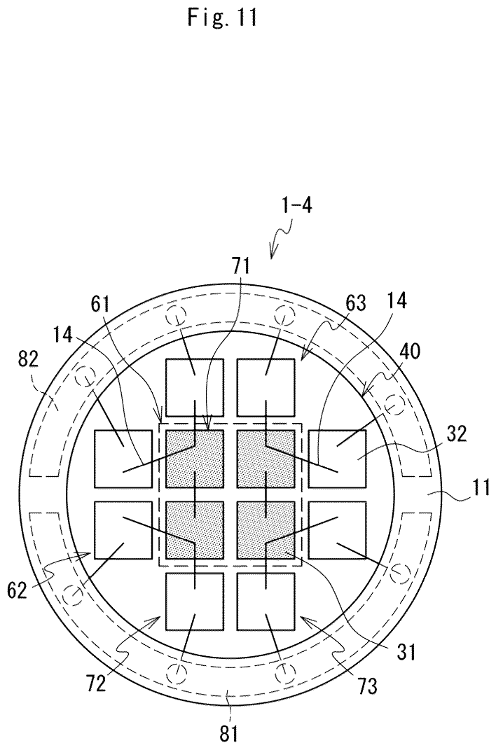

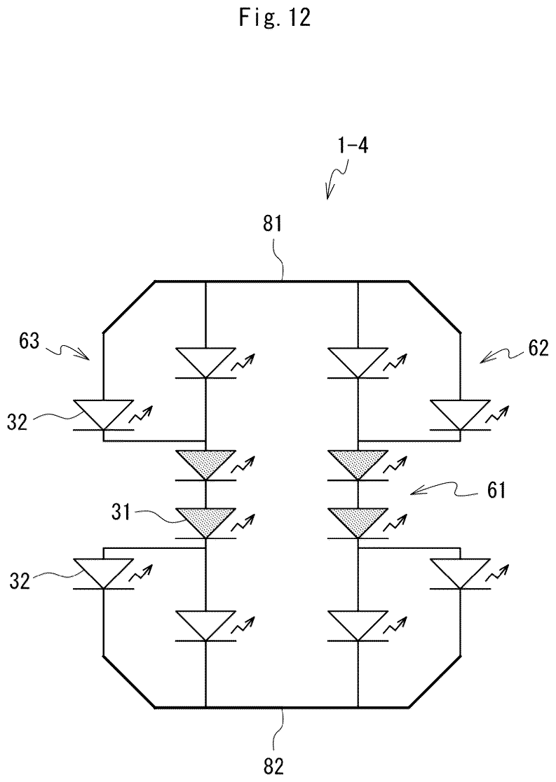

FIGS. 11 and 12 show a light-emitting device 1-4 according to a fifth embodiment of the present invention. In the light-emitting device 1-4, a pair of second light-emitting element groups 62 and 63 are disposed on both sides of a first light-emitting element group 61 with the element group 61 interposed therebetween in a mounting region of a light exit surface 40. A first power supply pad 81 is coupled to one of the pair of second light-emitting element groups 62 and 63, and a second power supply pad 82 is coupled to the other. The first power supply pad 81 and the second power supply pad 82 are disposed on a lower surface side of a reflection frame body 11 having a ring shape surrounding the light exit surface 40. When an electric current flows from a first power supply terminal (not shown) toward a second power supply terminal 22, a plurality of first light-emitting elements 31 constituting the light-emitting element group 61 and a plurality of second light-emitting elements 32 constituting the second light-emitting element groups 62 and 63 light up.

The first light-emitting element group 61 includes two first light-emitting element rows 71, each of which includes two first light-emitting elements 31. The pair of second light-emitting element groups 62 and 63 respectively include four second light-emitting element rows 72 and 73, each of which includes one second light-emitting element 32. The two first light-emitting element rows 71 are connected in parallel. Although the four second light-emitting element rows 72 and the four second light-emitting element rows 73 are connected in parallel, the first light-emitting element row 71 and the second light-emitting element rows 72 and 73 are directly connected in series by a bonding wire 14 without interposing an electrode pad therebetween.

A plurality of bonding wires 14 may be coupled to an anode electrode or a cathode electrode of each of the first light-emitting element 31 of the first element row 71 and the second light-emitting elements 32 of the second light-emitting element rows 72 and 73 which are directly coupled to each other. Two or fewer bonding wires 14 are preferably coupled to the anode electrode or the cathode electrode in terms of process and durability. That is, the ratio of number of rows, which is a value obtained by dividing a sum of the numbers of rows of the second light-emitting element rows 72 and 73 respectively constituting the second light-emitting element groups 62 and 63 by a value of the number of rows of the first light-emitting element rows 71 constituting the first light-emitting element group 61, is preferably 2 or fewer.

Similarly to the arrangement of the light-emitting elements in the fourth embodiment shown in FIG. 10, four first light-emitting elements 31 are disposed at a central part of the light exit surface 40, and eight second light-emitting elements 32 surround the first light-emitting elements 31. Also in this embodiment, the first light-emitting elements 31 are disposed at the central part of the light exit surface 40, and the second light-emitting elements 32 surround the first light-emitting elements 31. Consequently, luminance of the central part of the light exit surface 40 can be enhanced, and its surroundings have uniform lightness.

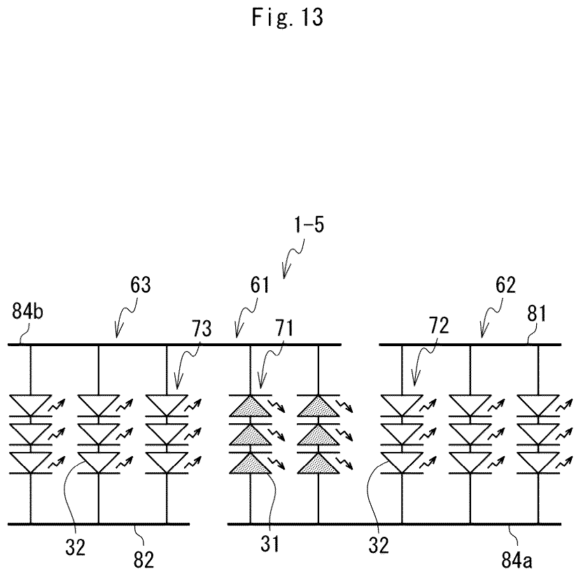

FIG. 13 shows a light-emitting device 1-5 according to a sixth embodiment of the present invention. Similarly to the light-emitting device 1-4 according to the fifth embodiment, in the light-emitting device 1-5, a pair of second light-emitting element groups 62 and 63 are respectively disposed on both sides of a first light-emitting element group 61 with the element group 61 interposed therebetween. A first power supply pad 81 is coupled to one of the pair of second light-emitting element groups 62 and 63, and a second power supply pad 82 is coupled to the other. This embodiment is different from the light-emitting device 1-4 according to the fifth embodiment in the point that first light-emitting element rows 71 constituting the first light-emitting element group 61 and second light-emitting element rows 72 and 73 respectively constituting the pair of second light-emitting element groups 62 and 63 are coupled by an opposing electrode pad. Specifically, an opposing electrode pad 84a is coupled to another end of one of the second light-emitting element rows 72 coupled to the first power supply pad 81 and one end of the first light-emitting element row 71, and an opposing electrode pad 84b is coupled to the other end of the first light-emitting element row 71 and one end of the other second light-emitting element row 73 to which the second power supply pad 82 is coupled. The power supply pads and the electrode pads are disposed on a lower surface side of a reflection frame body having a rectangular shape or a ring shape surrounding a light exit surface. When an electric current flows from a first power supply terminal toward a second power supply terminal, a plurality of first light-emitting elements 31 constituting the light-emitting element group 61 and a plurality of second light-emitting elements 32 constituting the second light-emitting element groups 62 and 63 light up.

The first light-emitting element group 61 includes two first light-emitting element rows 71, each of which includes two first light-emitting elements 31. The pair of second light-emitting element groups 62 and 63 respectively include three second light-emitting element rows 72 and 73, each of which includes three second light-emitting elements 32. The two first light-emitting element rows 71 are connected in parallel. Although the three second light-emitting element rows 72 and the three second light-emitting element rows 73 are connected in parallel, the first light-emitting element row 71 and the second light-emitting element rows 72 and 73 are connected in series by interposing the opposing electrode pad 84a and 84b therebetween.

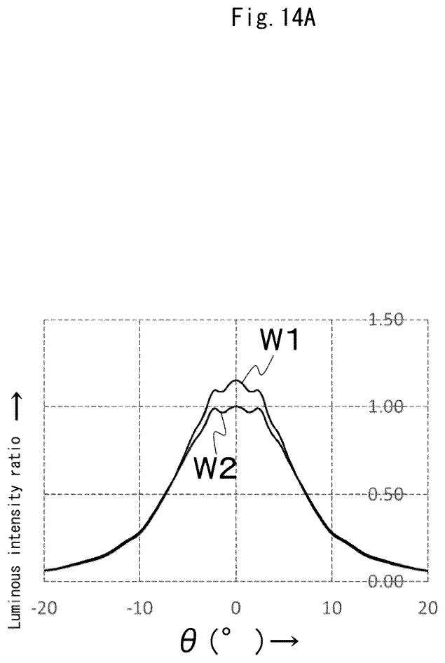

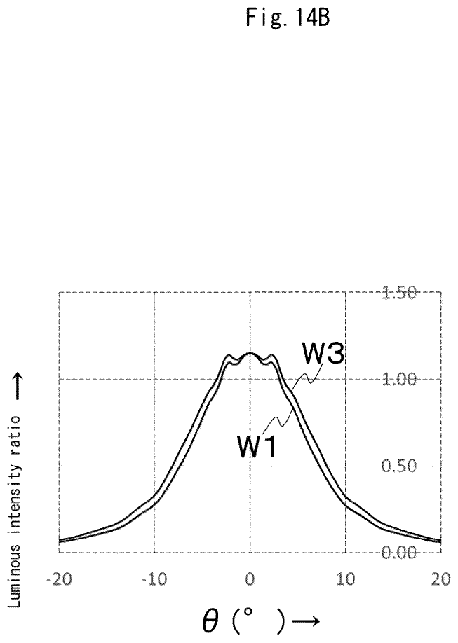

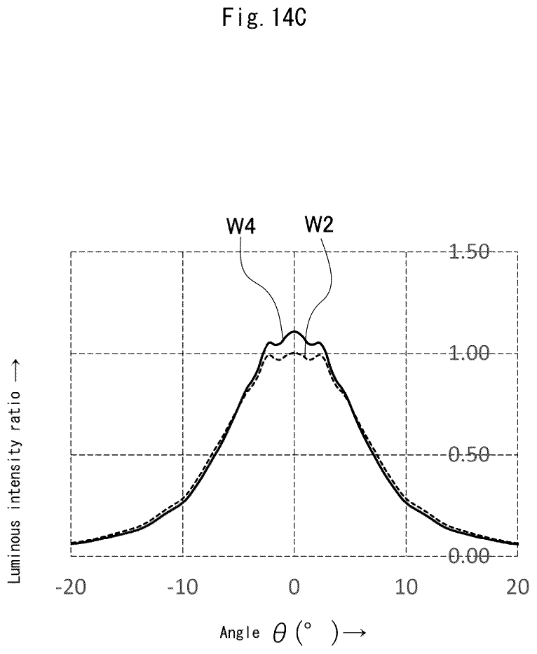

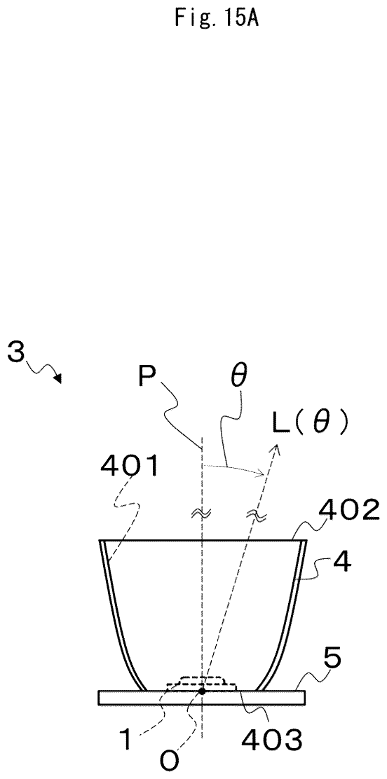

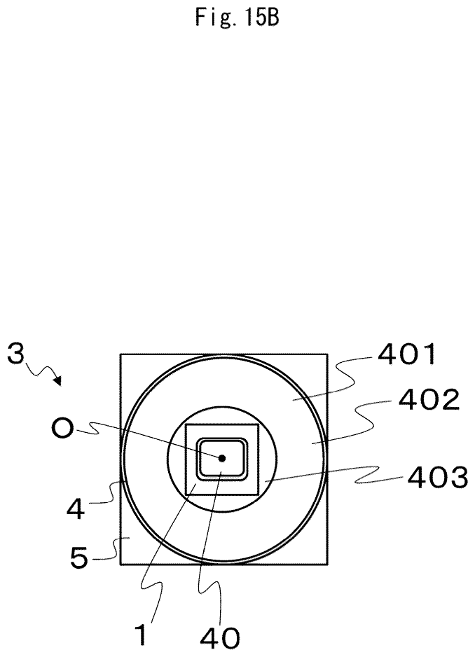

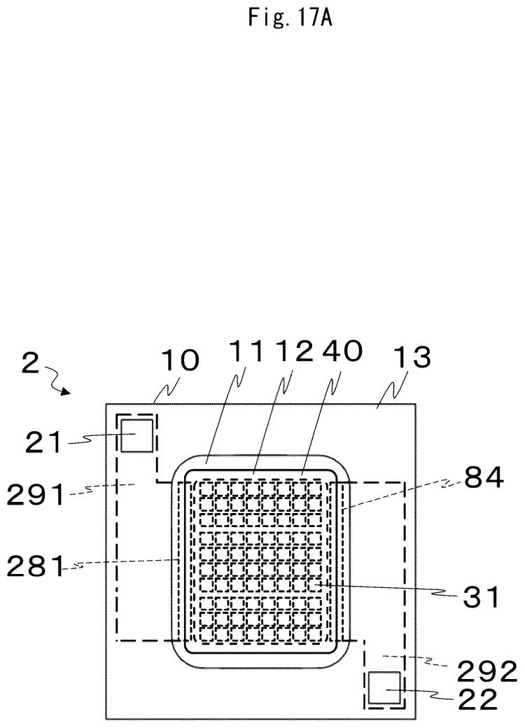

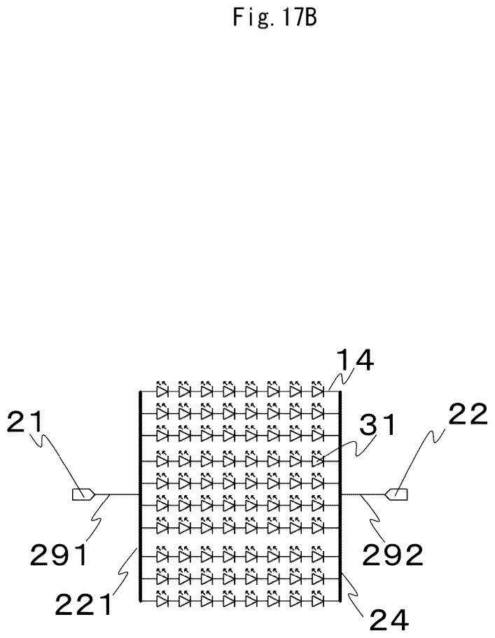

FIG. 14A is a characteristic diagram (part 1) showing luminous intensity distributions of a lighting apparatus 3 according to the present embodiment shown in FIGS. 15A and 15B, and a lighting apparatus using the light-emitting device 2 according to a comparative example shown in FIGS. 17A and 17B. FIG. 14B is a characteristic diagram (part 2) showing luminous intensity distributions of the lighting apparatus 3 according to the present embodiment, and the lighting apparatus using the light-emitting device 2 according to the comparative example. The lighting apparatus 3 according to the present embodiment uses the light-emitting device 1 according to the first embodiment.

FIG. 15A is a front view of the lighting apparatus 3 according to the present embodiment, and FIG. 15B is a plan view of the lighting apparatus 3 according to the present embodiment.

The lighting apparatus 3 according to the present embodiment includes the light-emitting device 1, a reflector 4 as a condenser that collects and emits light emitted from the light-emitting device 1, and a base 5 with an upper surface where the light-emitting device 1 and the reflector 4 are disposed. The light-emitting device 1 is disposed on the upper surface of the base 5, and emits light when electric power is supplied from an external power supply (not shown).

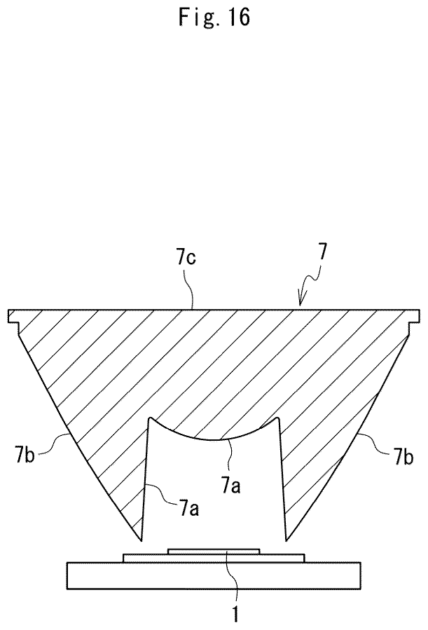

The reflector 4 includes an upper surface opening 402 and a bottom surface opening 403, and includes a reflection surface 401 between the upper surface opening 402 and the bottom surface opening 403. The bottom surface opening 403 is an opening disposed so as to cover the light-emitting device 1 on the upper surface of the base 5. The reflection surface 401 is a reflection surface that reflects the light emitted from the light-emitting device 1 toward the upper surface opening 402. The upper surface opening 402 is an opening that allow exit of light reflected from the reflection surface 401. An external shape of the reflection surface 401 is a circular shape in plan view. A centroid of the light exit surface 40 of the light-emitting device 1 is designed to coincide with a center of a circle that is the external shape of the reflection surface 401. In plan view, light emitted from a position of the center of the circle that is the external shape of the reflection surface 401 is condensed and efficiently exited from the upper surface opening 402. As an example, a diameter of an outermost shape of the reflection surface 401 is 60 mm, and a distance from the bottom surface opening 403 to the upper surface opening 402 is 45 mm. A condenser other than the reflector 4 may be, for example, a condenser lens 7 as shown in FIG. 16. The condenser lens 7 is disposed so as to cover the light-emitting device 1 from above, and includes an incident face 7a through which light emitted from the light-emitting device 1 enters, a reflection surface 7b that reflects the light that has entered the lens, and an exit surface 7c that exits the light in the lens upward.

The lighting apparatus 3 emits light of a luminous intensity Lθ (cd) in a direction of an angle θ (°) with respect to an axis P that passes through the center of the circle being the external shape of the reflection surface 401 in plan view and extends in parallel to a normal direction of the upper surface of the base 5. The light intensity Lθ is measured using a photometer (not shown) at positions located at equal distance from a point O that is an intersection of the axis P and the upper surface of the base 5. A distance between the point O and the position at which the luminous intensity is measured is a distance called a far field region, which is, for example, 1 m.

The lighting apparatus using the light-emitting device 2 according to the comparative example is different from the lighting apparatus 3 in the point that the light-emitting device 2 is used instead of the light-emitting device 1. Configuration and functions of structural elements are approximately the same as those of the lighting apparatus 3, except that the light-emitting device 2 is used instead of the light-emitting device 1.

FIG. 17A is a front view of the light-emitting device 2 according to the comparative example. FIG. 17B is a circuit diagram of the light-emitting device 2 according the comparative example. The bonding wire 14 is omitted in FIG. 17A.

The light-emitting device 2 according to the comparative example is different from the light-emitting device 1 in the point that first power supply wiring 291, second power supply wiring 292, and a first power supply pad 281 are included instead of the first power supply wiring 91, the second power supply wiring 92, and the first power supply pad 81. The light-emitting device 2 according to the comparative example includes no second light-emitting elements 32, but includes first light-emitting elements 31 whose number is equal to a sum of the numbers of the first light-emitting device 31 and the second light-emitting devices 32 of the light-emitting device 1, and the first light-emitting elements 32 of the light-emitting device 2 are coupled in the same direction. Because the configurations and functions of the structural elements of the light-emitting device 2 other than the first power supply wiring 291, the second power supply wiring 292, the first power supply pad 281, and the first light-emitting elements 31 are the same as the configurations and functions of the structural elements of the light-emitting device 1 denoted by the same reference numerals, their detailed description will be omitted.

The light-emitting device 2 includes a first power supply terminal 21 and a second power supply terminal 22 that are a pair of power supply terminals. The first power supply terminal 21 is coupled via first power supply wiring 291 to the first power supply pad 281. The second power supply terminal 22 is coupled via second power supply wiring 292 to an opposing electrode pad 84. A light-emitting element row where eight first light-emitting elements 31 are connected in series with a bonding wire 14 interposed therebetween is disposed between the first power supply pad 281 and the opposing electrode pad 84. Then, 80 first light-emitting elements 31 are coupled between the first power supply terminal 21 and the second power supply terminal 22 by connecting ten light-emitting element rows in parallel in the same direction. Each of the light-emitting element rows includes the first light-emitting element 31 at an initial stage whose anode electrode is coupled via the bonding wire 14 to the first power supply pad 281, and the first light-emitting element 31 at a final stage whose cathode electrode is coupled via the bonding wire 14 to the opposing electrode pad 84.

When electric power is supplied between the first power supply terminal 21 and the second power supply terminal 22 in the light-emitting device 2, an electric current having the same current value flows to the 80 first light-emitting elements 31 coupled between the first power supply terminal 21 and the second power supply terminal 22. Accordingly, amounts of luminous flux of light emitted from the individual first light-emitting elements 31 are equal to each other.

W1 and W2 shown in FIG. 14A are curves showing luminous intensity distributions when electric power of an identical electric energy W is supplied to each of the lighting apparatus 3 using the light-emitting device 1 and the lighting apparatus using the light-emitting device 2. An abscissa of the characteristic diagram shown in FIG. 14A indicates a value of light emission angle θ (unit is degree), and an ordinate is a value of a normalized luminous intensity ratio at θ. The characteristic diagram shows the value of the luminous intensity ratio normalized assuming that a light intensity Lθ at θ=0 when electric power of electric energy W is supplied to the lighting apparatus using the light-emitting device 2 is 1.00.

FIG. 14A shows that a value of W2 at θ=0 is 1.00, and a value of W1 is 1.15. The value of W1 is larger than the value of W2 and a difference between the value of W1 and the value of W2 is 0.03 or more in a range of −5≤θ≤5. The value of W1 is equal to the value of W2 in the vicinity of θ=±6.5. The value of W1 is smaller than the value of W2, and a difference between the value of W1 and the value of W2 is −0.01 or more and 0.01 or less in a range of θ≤−7 or 7≤θ. The lighting apparatus 3 according to the present embodiment is capable of enhancing irradiation in a specific direction as compared to the lighting apparatus using the light-emitting device 2 to which the electric power of the identical electric energy W is supplied.

An abscissa and an ordinate of the characteristic diagram shown in FIG. 14B show the same values as the values shown by the abscissa and the ordinate of the characteristic diagram shown in FIG. 14A.

W1 shown in FIG. 14B is the same as W1 shown in FIG. 14A, and is a curve showing a luminous intensity distribution when electric power of an electric energy W is supplied to the lighting apparatus 3. W3 is a curve showing a luminous intensity distribution when electric power of an electric energy Wa is supplied to the lighting apparatus using the light-emitting device 2. The electric energy Wa is electric energy set so that a value of W3 at θ=0 becomes equal to the value of W1 at θ=0. As an example, the electric energy Wa is 1.2 times the electric energy W.

In FIG. 14B, both of the value of W1 and the value of W3 at θ=0 are 1.15. The value of W3 is higher than the value of W1 in a region of values at other than θ=0. For example, a value of W1 is 0.66 and a value of W3 is 0.76 at θ=6.5.

With the lighting apparatus 3, the electric energy of electric power supplied can be reduced as compared to the lighting apparatus using the light-emitting device 2 that is set to luminous intensity in the same front direction.

The light-emitting device 1 according to the present embodiment is capable of efficiently enhancing irradiation in a specific direction as compared to the light-emitting device 2.

An abscissa and an ordinate of the characteristic diagram shown in FIG. 14C show the same values as the values shown by the abscissa and the ordinate of the characteristic diagram shown in FIG. 14A. W2 shown in FIG. 14C is the same as W2 shown in FIG. 14A, and is a curve showing a luminous intensity distribution when electric power of the electric energy W is supplied to the lighting apparatus using the light-emitting device 2. W4 is a curve showing a luminous intensity distribution when electric power of electric energy Wb is supplied to the lighting apparatus 3. The electric energy Wb is lower than the electric energy W, and is electric energy set so that a value of W4 is higher than a value of W2 at θ<|5|, and the value of W4 is lower than the value of W2 at θ>|5|. As an example, the electric energy Wb is 0.96 times the electric energy W.

In FIG. 14C, the value of W4 at θ=0 is 1.10 and is higher than W2. The value of W4 is higher than W2 at θ<|5|. W4 and W2 have approximately the same value at θ=|5|. W4 has a lower value than W2 at θ>|5 |.

Compared to the lighting apparatus using the light-emitting device 2 set to luminous intensity of the same front direction, the lighting apparatus 3 is capable of enhancing emission toward a specific direction (for example, a range of θ<|5|) and turning down emission toward a direction other than the specific direction (for example, a range of θ>|5|), and is also capable of reducing the electric energy of electric power supplied.

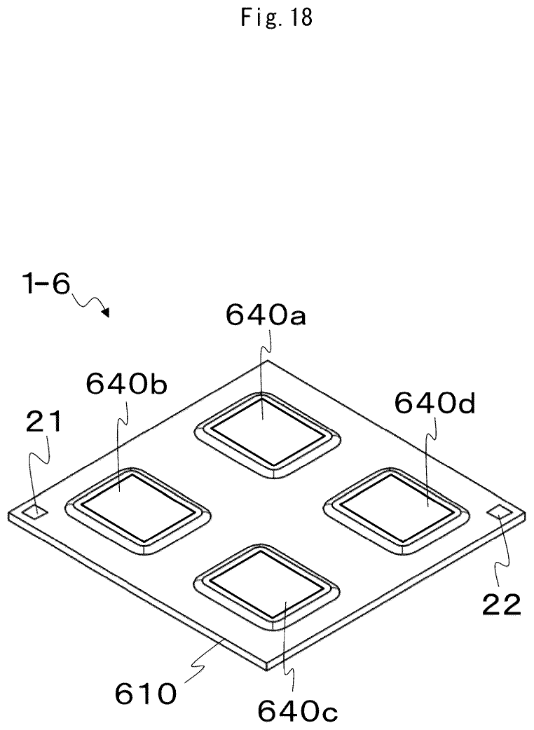

FIG. 18 is a perspective view of a light-emitting device 1-6 according to a seventh embodiment of the present invention.

The light-emitting device 1-6 according to the seventh embodiment is different from the light-emitting device 1 in the point that a substrate 610 and a plurality of light exit surfaces 640a to 640d are included instead of the substrate 10 and the light exit surface 40. Because the configurations and functions of the structural elements of the light-emitting device 1-6 other than the substrate 610 and the light exit surfaces 640a to 640d are the same as the configurations and functions of the structural elements of the light-emitting device 1, their detailed description will be omitted.

The substrate 610 is different in front shape from the substrate 10. The substrate 610 has the same configurations and functions as the substrate 10 except for the front shape. The substrate 610 has the front shape of a square with a side length of 40 mm in the present embodiment.

The light-emitting device 1-6 is different from the light-emitting device 1 in the point of including a plurality of light exit surfaces. The present embodiment includes four light exit surfaces 640a to 640d. The number of the light exit surfaces may be two, three, or five or more.

In the light-emitting device 1-6, when a potential difference of a threshold value or more is applied between a first power supply terminal 21 and a second power supply terminal 22 that are a pair of power supply terminals, an electric current flows from the first power supply terminal 21 toward the second power supply terminal 22, thereby supplying electric power. When the electric current flows from the first power supply terminal 21 toward the second power supply terminal 22, the four light exit surfaces 640a to 640d individually emit light.

The light exit surfaces 640a to 640d, each having the same configurations and functions of the structural elements of the light exit surface 40, are spaced apart from one another.

### Reference Signs List

1, 1-1 to 1-6, 2 . . . Light-emitting device, 3 . . . Lighting apparatus, 4 . . . Reflector (Condenser), 5 . . . Base, 7 . . . Condenser lens (Condenser), 7a . . . Incident surface, 7b . . . Reflection surface, 7c . . . Exit surface, 8 . . . Black band, 9 . . . White band, 10, 610 . . . Substrate, 11 . . . Reflection frame body, 12 . . . Sealing material, 13 . . . Insulating film, 14 . . . Bonding wire, 21 . . . First power supply terminal, 22 . . . Second power supply terminal, 31 . . . First light-emitting element, 32 . . . Second light-emitting element, 40, 640a to 640d . . . Light exit surface 41 . . . First light exit region, 42, 43 . . . Second light exit region, 50 . . . Mounting region, 51 . . . First mounting region, 52, 53 . . . Second mounting region, 60 . . . Light-emitting element group, 61 . . . First light-emitting element group, 62, 63 . . . Second light-emitting element group, 71 . . . First light-emitting row, 72, 73 . . . Second-light emitting element row, 81, 281 . . . First power supply pad, 82 . . . Second power supply pad, 83 . . . Third power supply pad, 84 . . . Opposing electrode pad, 91, 291 . . . First power supply wiring, 92, 292 . . . Second power supply wiring

1.-cm 17. (canceled)

18. A light-emitting device comprising:
a substrate;
a pair of power supply terminals disposed on the substrate;
a plurality of first light-emitting elements and a plurality of second light-emitting elements which are configured to emit light by supplying electric power between the pair of power supply terminals; and
a light exit surface configured to allow exit of light emitted from the plurality of first light-emitting elements and the plurality of second light-emitting elements,
wherein the light exit surface comprises a first light exit region being a plane region including a centroid of the light exit surface in plan view, and a second light exit region being a plane region not including the first light exit region,
wherein the plurality of first light-emitting elements constitute a first light-emitting element group by being disposed in the first light exit region in plan view, and the plurality of second light-emitting elements constitute a second light-emitting element group by being disposed in the second light exit region in plan view,
wherein the first light-emitting element group comprises a plurality of first light-emitting element rows where the plurality of first light-emitting elements are arranged, and a clearance between individual elements of the plurality of first light-emitting elements constituting the first light-emitting element rows and an interval between the first light-emitting element rows are smaller than an element size of each of the first light-emitting elements,
wherein the second light-emitting element group comprises a plurality of second light-emitting element rows where the plurality of second light-emitting elements are arranged, and a clearance between individual elements of the plurality of second light-emitting elements constituting the second light-emitting element rows and an interval between the second light-emitting element rows is smaller than an element size of each of the second light-emitting elements,
wherein an interval between the first light-emitting element rows and the second light-emitting element rows is smaller than the element size of each of the first light-emitting elements and each of the second light-emitting elements, and
wherein an average luminance of light exited from the first light exit region is higher than an average luminance exited from the second light exit region.

19. The light-emitting device according to claim 18, wherein the first light exit region is disposed at a central part of the light exit surface in plan view, and the second light exit region is disposed at both sides of the light exit surface with the first light exit region interposed therebetween in plan view.

20. The light-emitting device according to claim 19, wherein the light exit surface is formed in a rectangular or circular shape in plan view.

21. The light-emitting device according to any one of claims 18, wherein the light exit surface is surrounded by a reflection frame body having a rectangular frame shape or a ring shape.

22. The light-emitting device according to claim 18,
wherein the plurality of first light-emitting elements constituting each of the plurality of first light-emitting element rows are connected in series, and the plurality of second light-emitting elements constituting each of the plurality of second light-emitting element rows are mutually connected in series.

23. The light-emitting device according to claim 22, wherein the plurality of first light-emitting elements and the plurality of second light-emitting elements are individually connected in series by a bonding wire.

24. The light-emitting device according to claim 22, wherein electric power supplied to the first light-emitting element is larger than electric power supplied to the second light-emitting element.

25. The light-emitting device according to claim 18,
wherein the first light-emitting element group comprises the plurality of first light-emitting element rows coupled in parallel between a first power supply pad and an opposing electrode pad, and
wherein the second light-emitting element group comprises the plurality of second light-emitting element rows connected in parallel between the opposing electrode pad and a second power supply pad.

26. The light-emitting device according to claim 25, wherein the first power supply pad and the opposing electrode pad are disposed on both sides of the plurality of first light-emitting element rows with the first light-emitting element rows interposed therebetween, and the opposing electrode pad and the second power supply pad are disposed on both sides of the plurality of second light-emitting element rows with the second light-emitting element rows interposed therebetween.

27. The light-emitting device according to claim 26, wherein the first power supply pad, the opposing electrode pad, and the second power supply pad are disposed on the substrate and are disposed on a lower surface side of a dam having a rectangular frame shape or a ring shape disposed around the first light-emitting element group and the second light-emitting element group.

28. The light-emitting device according to claim 26, wherein the first power supply pad and the second power supply pad are disposed adjacent to each other, and the opposing electrode pad is disposed at a position opposed to the first power supply pad and the second power supply pad.

29. The light-emitting device according to claim 18, wherein second light-emitting element groups comprising the plurality of second light-emitting element rows are respectively disposed on both sides of the first light-emitting element group comprising the plurality of first light-emitting element rows with the first light-emitting element group interposed therebetween, and the first light-emitting element group and the second light-emitting element groups are connected in series, whereas the plurality of second light-emitting element rows are connected in parallel to each other.

30. The light-emitting device according to claim 29, wherein a first power supply pad is coupled to one end of the second light-emitting element row constituting one of the second light-emitting element groups respectively disposed on both sides of the first light-emitting element group, and a second power supply pad is coupled to the other end of the second light-emitting element row constituting the other second light-emitting element group.

31. The light-emitting device according to claim 30, wherein a first opposing electrode pad is coupled to the other end of the second light-emitting element row constituting the one second light-emitting element group and one end of the first light-emitting element row constituting the first light-emitting element group, and a second opposing electrode pad is coupled to the other end of the first light-emitting element and one end of the second light-emitting element row constituting the other second light-emitting element group.

32. The light-emitting device according to claim 25, wherein a number of the plurality of first light-emitting element rows is smaller than a number of the plurality of second light-emitting element rows.

33. The light-emitting device according to claim 18, comprising a plurality of light exit surfaces, the light exit surfaces being disposed apart from one another on the substrate.

34. A lighting apparatus comprising:
the light-emitting device according to claim 18; and
a condenser disposed above the light exit surface.
